(19) United States
(12) Patent Application Publication
(10) Pub. No.: US 2011/0220192 A1
(43) Pub. Date: Sep. 15, 2011

(54) SINGLE-SIDED DYE-SENSITIZED SOLAR CELLS HAVING A VERTICAL PATTERNED STRUCTURE

(76) Inventors: Fariba Tajabadi, Kerman (IR); Nima Taghavinia, Tehran (IR)

(21) Appl. No.: 13/113,052

(22) Filed: May 22, 2011

Related U.S. Application Data
(60) Provisional application No. 61/347,432, filed on May 23, 2010.

(51) Int. Cl. H01L 31/0352; H01L 51/44

(52) U.S. Cl. 136/255

(57) ABSTRACT

A single-sided dye-sensitized solar cell having a vertical patterned structure is disclosed. A patterned nonconductive insulating layer is formed directly over first portions of a conductive substrate. An electrocatalyst material layer is formed directly over second portions of the conductive substrate, where the second portions of the conductive substrate do not overlap with the first portions of the conductive substrate. A second conductive layer is formed directly over the patterned nonconductive insulating layer and a porous layer is formed directly over the second conductive layer. An electrolyte is formed over the porous layer and the electrocatalyst material layer and a transparent sheet is formed over the electrolyte.

### CROSS-REFERENCE TO RELATED APPLICATIONS

The present application claims the benefit of U.S. Provisional Patent Application Ser. No. 61/347,432, filed on May 23, 2010, which is incorporated herein by reference in its entirety.

### SPONSORSHIP STATEMENT

This application has been sponsored by the Iranian Nanotechnology Initiative Council and the Sharif University of Technology, which do not have any rights in this application.

### TECHNICAL FIELD

This application generally relates to dye-sensitized solar cells, and more particularly relates to single-sided dye-sensitized solar cells having a vertical patterned structure.

### BACKGROUND

A dye-sensitized solar cell (hereinafter “DSC”) is a photoelectrochemical cell that converts solar energy into electrical power. An example structure of a conventional DSC is illustrated in FIG. 1. The conventional DSC includes a mesoporous layer 12 made up of a large bandgap semiconductor material, which is sensitized using a monolayer of an appropriate dye that acts as a photo-anode. The mesoporous layer 12 is deposited on a glass substrate 10 with a transparent conducting oxide (hereinafter “TCO”) layer 11, such as, for example, fluorine-doped tin oxide (hereinafter “FTO”). A counter electrode can be made up of a FTO layer 16 deposited on another glass substrate 17 and adjacent to a thin layer 15 made up of, for example, platinum (Pt) or carbon (C). The TCO layer 11 and the thin layer 15 are separated by, for example, about 50 μm and sealed on the sides by spacers 13.

The volume between the TCO layer 11 and the thin layer 15 is filled with an electrolyte 14 that can include, for example, I⁻/I₃⁻ redox species. The dye molecules adsorbed on the surface of the mesoporous layer 12 act to absorb light photons and inject the resulting excited electrons to the mesoporous layer 12, resulting in electrical power production within the DSC.

Since the first DSC structure was introduced in the early 1990s, many efforts have been made to enhance the efficiency and reduce the fabrication costs of the cells. Currently, DSC efficiency measured in laboratories has improved from 7% to about 12%, which is below the efficiency of silicon and thin film solar cells. While research to improve the efficiency of DSCs is continuing, efforts are also being made to reduce fabrication costs by replacing components within a DSC with a more readily available, lower priced components.

A considerable fraction, up to about 25%, of the fabrication costs of a DSC is due to the FTO glass used. Moreover, FTO glass poses limitations in the fabrication of DSCs, due to its limited conductivity and transparency. The conductivity and transparency in FTO glass are inversely related, i.e., the higher the conductivity, the lower the transparency and vice-versa. Typically, the resistivity of FTO glass is about 8 Ω/cm². In the case of DSCs tested in a laboratory that are a few millimeters in size, this resistivity does not greatly impact the performance of the DSCs. However, in large modules, the series resistance of the FTO layer may reduce the fill factor and current density of the modules. Reducing the resistivity of FTO layers may be possible by optimizing the chemical composition of the layer, as well as its thickness. However, within feasible conditions, the resistivity cannot be reduced by more than a factor of 4. By comparison, the resistivity of other metals is typically 100 times less than FTO.

In addition, FTO glass is not fully transparent. At least some, typically about 25%, of the light incident on FTO glass is reflected and, thus, not absorbed. Less light must be reflected to increase the efficiency of DSCs in the future.

Also, in a conventional DSC structure, an electrolyte 14 or a hole conductive layer provides electrical conductance between the working and counter electrodes. Acetonitrile electrolytes, which use I⁻/I₃⁻ as the redox couple, are common electrolytes that provide high performance. In these electrolytes, diffusion of the I₃⁻ species limits ion conductivity at high current densities. The limitations posed by such diffusion are critical, as the diffusion forces use of low viscosity electrolytes with relatively high vapor pressures. The evaporation of low viscosity electrolytes can lead to short cell life.

The distance between the electrodes is controlled by the spacers 13 that seal the DSC. Due to ion diffusion, it is also important that the distance between the working and counter electrodes be as short as possible. However, in conventional DSCs, the distance between the two electrodes cannot be lower than a certain level due to possible contact between the electrodes, resulting in short-circuiting.

### SUMMARY

A single-sided dye-sensitized solar cell having a vertical patterned structure is disclosed. A patterned nonconductive insulating layer is formed directly over first portions of a conductive substrate. An electrocatalyst material layer is formed directly over second portions of the conductive substrate, where the second portions of the conductive substrate do not overlap with the first portions of the conductive substrate. A second conductive layer is formed directly over the patterned nonconductive insulating layer and a porous layer is formed directly over the second conductive layer. An electrolyte is formed over the porous layer and the electrocatalyst material layer and a transparent sheet is formed over the electrolyte.

In some implementations, the single-sided dye-sensitized solar cell can include two or more spacers located between the conductive substrate and the transparent sheet at opposite ends of the single-sided dye-sensitized solar cell. The volume between the two or more spacers, the conductive substrate, and the transparent sheet can include the electrolyte.

In some implementations, the first portions of the conductive substrate and the second portions of the conductive substrate can be interdigitated. The conductive substrate can include one or more conductive materials selected from the group consisting of copper, nickel, chromium, titanium, stainless steel, and silicon. The patterned nonconductive insulating layer can include one or more nonconductive insulating materials selected from the group consisting of silicon oxides, silicon nitride, zirconium oxide, and aluminum oxide. The patterned nonconductive insulating layer can include one or more polymers.

In some implementations, the porous layer can include one or more of titanium dioxide and/or zinc oxide. The titanium dioxide can include titanium dioxide nanoparticles and the zinc oxide can include zinc oxide nanoparticles. The porous layer can include one or more dye sensitizers and/or quantum dot sensitizers.

In some implementations, the electrocatalyst material layer can include one or more electrocatalyst materials selected from the group consisting of platinum and cobalt sulfide. The second conductive layer can include one or more conductive materials selected from the group consisting of copper, nickel, chromium, titanium, and stainless steel.

In some implementations, the thickness of the second conductive layer can range from 100 nm to 100 μm, the width of the patterned nonconductive insulating layer, the second conductive layer, and the porous layer can range from 10 μm to 100 μm, and the width of the electrocatalyst material layer can range from 5 μm to 100 μm. The width of the patterned nonconductive insulating layer, the second conductive layer, and the porous layer can be greater than the width of the electrocatalyst material layer.

Another single-sided dye-sensitized solar cell having a vertical patterned structure is also disclosed. A photo-anode is formed including a patterned nonconductive insulating layer formed directly over first portions of a conductive substrate, a second conductive layer formed directly over the patterned nonconductive insulating later, and a porous layer formed directly over the second conductive layer. A cathode is formed including an electrocatalyst material layer formed directly over second portions of the conductive substrate, wherein the second portions of the conductive substrate do not overlap with the first portions of the conductive substrate. An electrolyte is formed over the photo-anode and the cathode and a transparent sheet is formed over the electrolyte.

Details of one or more implementations of the single-sided dye-sensitized solar cells having a vertical patterned structure are set forth in the accompanying drawings and the description below. Other aspects that can be implemented will be apparent from the description and drawings, and from the claims.

### DESCRIPTION OF DRAWINGS

FIG. 1 illustrates the structure of a conventional DSC.

FIG. 2a illustrates the structure of an implementation of a DSC having two electrodes separated vertically on a single side of the cell.

FIG. 2b illustrates a three-dimensional perspective view of the DSC illustrated in FIG. 2a showing two vertically-separated electrodes.

FIG. 3a illustrates the structure of an implementation of a DSC having two electrodes separated horizontally on a single side of the cell.

FIG. 3b is a top view of the DSC illustrated in FIG. 3a showing two horizontally-separated electrodes.

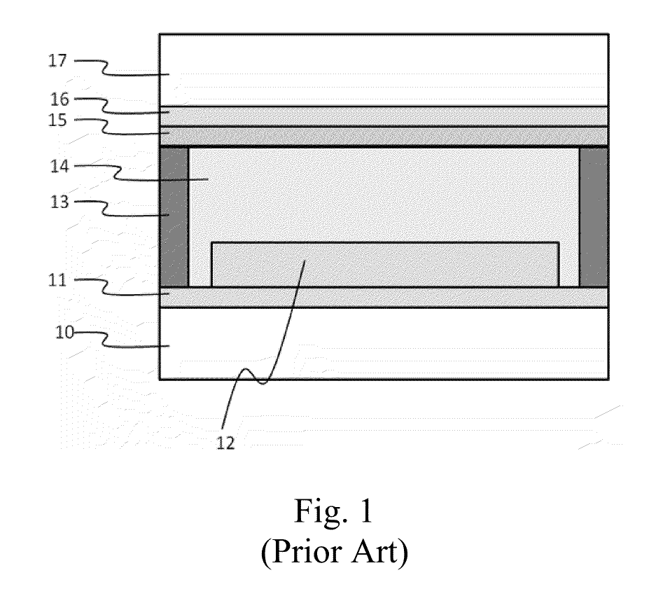

Like reference symbols indicate like elements throughout the specification and drawings.

### DETAILED DESCRIPTION

A new structure of a DSC that includes two vertically separated electrodes on a single side of the cell is disclosed. By including the working and counter electrodes on a single side of the cell, this structure eliminates the need for TCO glass within a DSC, leading to a considerable reduction in fabrication costs.

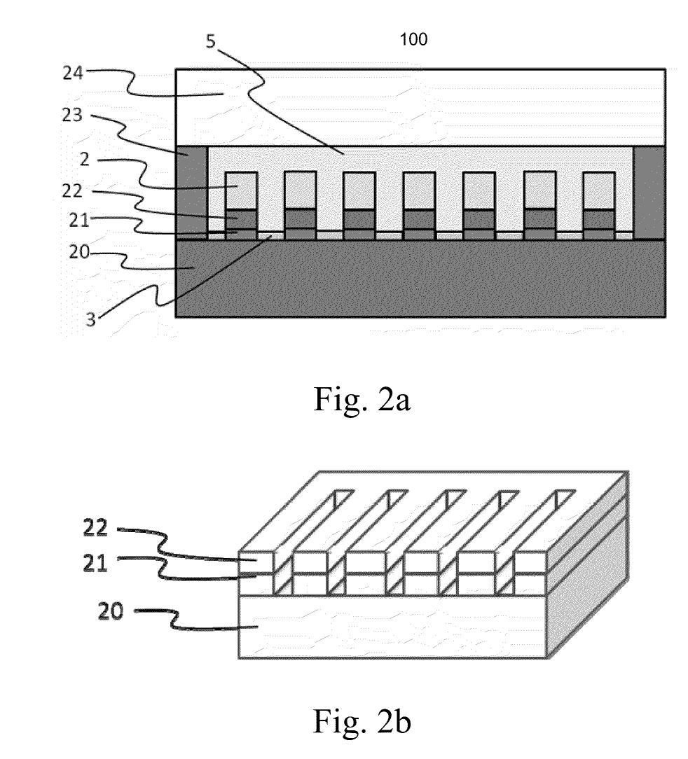

In one implementation, two electrodes of a DSC are patterned to be separated vertically. As illustrated in FIGS. 2a-2b, for example, a DSC 100 includes a conductive substrate 20, acting as one electrode, and a patterned metal layer 22, acting as the other electrode, separated by a nonconductive insulating material 21. The pattern of nonconductive insulating material 21 can be in the form of fingers that are to be interdigitated with an electrocatalyst material 3, as illustrated in FIG. 2a. In some implementations, the nonconductive insulating material 21 can be patterned identically to the patterned metal layer 22 to create an insulating layer between the conductive substrate 20 and the patterned metal layer 22. In other implementations, the nonconductive insulating material 21 can be patterned differently from the pattern metal layer 22, so that the nonconductive insulating material 21 and the pattern metal layer 22 do not completely overlap.

A porous layer 2, which can include, for example, titanium dioxide (TiO₂) and/or zinc oxide (ZnO), is deposited on one of the electrodes, such as the patterned metal layer 22. The titanium dioxide and/or zinc oxide particles in the porous layer 2 can be nanoparticles, i.e., particles that have an average size of less than 100 nm. A site-selective deposition method is used to deposit the porous layer 2, such as, for example, electrochemical deposition and electrophoretic deposition (hereinafter “EPD”).

The porous layer 2 can be loaded with one or more dye sensitizers and/or quantum dot sensitizers, such as, for example, N719, N3, black dye, and/or TT1 to act as a photo-anode. In some implementations, the dye sensitizers can be adsorbed on the surface of the porous layer 2 by soaking the porous layer 2 in a dye solution including the one or more dye sensitizers. In other implementations, a paste of semiconductor nanoparticles including the one or more dye sensitizers can be applied to the surface of the porous layer 2 by, for example, screen printing and/or doctor blade techniques.

The other electrode, such as the conductive substrate 20, is coated with an electrocatalyst material 3, which can be made up of, for example, platinum (Pt) or cobalt sulfide (CoS), to act as the cathode. The electrocatalyst material 3 is deposited in an interdigitated manner between the fingers of the nonconductive insulating material 21. A transparent sheet 24, which can be made of, for example, glass or plastic, is located opposite the conductive substrate 20 with spacers 23 located in-between at opposite ends of the DSC 100. The volume within the transparent sheet 24, spacers 23, and conductive substrate 20 can be filled with an electrolyte 5.

The conductive substrate 20 can be a polished metal sheet, a foil of a metal, or an insulating substrate coated with a metal layer. In some implementations, the conductive material can be one of more of, for example, copper (Cu), nickel (Ni), chromium (Cr), titanium (Ti), stainless steel, and/or silicon wafer. The metal can be selected based on the parameters of fabrication, such as compatibility with the electrochemical deposition process used to fabricate the DSC 100 and/or the metal's resistance to thermal or chemical degradation.

The nonconductive insulating material 21 on the conductive substrate 20 can be deposited by vapor deposition methods, such as, for example, evaporation, sputtering, and/or chemical vapor deposition; by chemical treatment, such as, for example, thermal oxidation and/or plasma nitridation; and/or by electrochemical methods, such as, for example, EPD. The type and thickness of the nonconductive insulating material 21 can be chosen to provide sufficient insulation between the conductive substrate 20 and the patterned metal layer 22, and remain stable during fabrication and in working conditions. The nonconductive insulating material 21 can include, for example, one or more of silicon oxides (SiO₂; SiO), silicon nitride (Si₃N₄), zirconium oxide (ZrO₂), and/or aluminum oxide (Al₂O₃). In some implementations, the nonconductive insulating material 21 can include one or more polymers.

The patterned metal layer 22 is deposited on the nonconductive insulating material 21 using any physical or chemical deposition method. The patterned metal layer 22 can be made up of one or more of, for example, copper (Cu), nickel (Ni), chromium (Cr), titanium (Ti), and/or stainless steel. The thickness of the patterned metal layer 22 can range from 100 nm to 100 μm. In some implementations, the patterned metal layer 22 and the nonconductive insulating material 21 can both be patterned in the interdigitated pattern illustrated in FIG. 2b, while in other implementations the patterned metal layer 22 and the nonconductive insulating material 21 can be patterned in another pattern.

The width of the channels including the electrocatalyst material 3 between the fingers of the nonconductive insulating material 21 and patterned metal layer 22 can range from 5 μm to 100 μm, and preferably being about 5 μm. In some implementations, the width of the channels including the electrocatalyst material 3 can be the same as the width of the nonconductive insulating material 21, whereas in other implementations, the width of the channels including the electrocatalyst material 3 can be different from, and preferably smaller than, the width of the nonconductive insulating material 21.

The spacers 23 are placed between the conductive substrate 20 and the transparent sheet 24. The spacers 23 can be made up of one or more thermoplastic polymers, such as, for example, anhydride-modified ethylene vinyl acetate polymers.

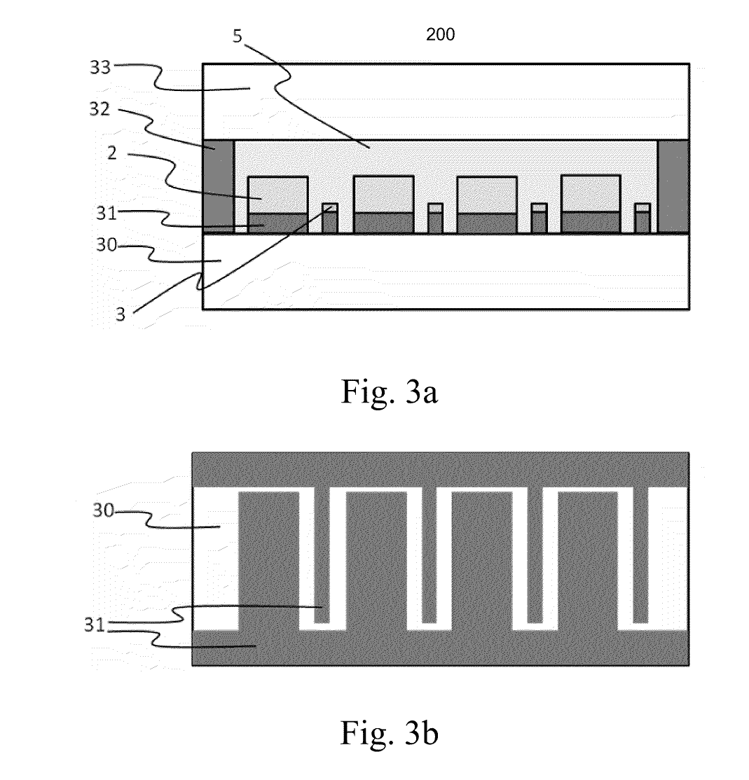

In another implementation, two electrodes of a DSC are patterned to be separated horizontally. As illustrated in FIGS. 3a and 3b, DSC 200 includes two finger patterns that are interwoven, i.e., in an interdigitated pattern. Each finger pattern can act as an electrode, with one finger pattern acting as an anode and its adjacent finger pattern acting as a cathode. An interdigitated metal layer 31 is patterned on an insulating substrate 30 to provide two horizontally-separated, interdigitated electrodes. The interdigitated metal layer 31 can be made up of one or more of, for example, copper (Cu), nickel (Ni), chromium (Cr), titanium (Ti), and/or stainless steel. The insulating substrate 30 can be made up of, for example, glass or plastic. The spacing between the adjacent fingers of the interdigitated metal layer 31 should be as small as possible to provide low cathode-anode electrolytic resistance, while retaining adequate insulation between the electrodes. In some implementations, for example, the spacing between the adjacent fingers of the interdigitated metal layer 31 can range between 5-100 μm.

A porous layer 2, which can include, for example, titanium dioxide (TiO₂) or zinc oxide (ZnO), is deposited on one of the horizontally-separated, interdigitated electrodes of the interdigitated metal layer 31. The porous layer 2 can be loaded with a dye sensitizer to act as a photo-anode. The other of the horizontally-separated, interdigitated electrodes of the interdigitated metal layer 31 can be coated with an electrocatalyst material 3, which can be made up of, for example, platinum (Pt) or cobalt sulfide (CoS), to act as the cathode.

A transparent sheet 33, which can be made of, for example, glass or plastic, is located opposite the insulating substrate 30 with spacers 23 located in-between at opposite ends of the DSC 200. The volume within the transparent sheet 33, spacers 32, and insulating substrate 30 can be filled with an electrolyte 5.

In both the vertical and horizontal electrode implementations disclosed above, light harvesting can be improved if a majority of the area on the substrate is covered by the photo-anode electrode rather than the cathode electrode. For example, referring to FIGS. 2a and 2b, the width of photo-anode fingers 20-22 can be wider than the width of cathode fingers 3. For example, the width of the photo-anode fingers 20-22 can range from 10-100 μm and the width of the cathode fingers can range from 5-100 μm. In some implementations, referring the FIGS. 3a and 3b, the width of photo-anode fingers 2, 31 can be wider than the width of cathode fingers 3, 31. However, in other implementations, the width of the photo-anode fingers 2, 31 and cathode fingers 3, 31 can be the same.

Moreover, the width of the cathode fingers in both the DSC 100 having the vertical electrode structure and the DSC 200 having he horizontal electrode structure, and the space between the photo-anode and cathode fingers in the DSC 200 should be minimized. One limitation in the minimization of the width of the cathode fingers and the space between the photo-anode and cathode fingers is the current capability to pattern fine structures on large areas. Whereas submicron lithography is now a routine in microelectronics, submicron lithography poses many challenges in the fabrication of large solar cells.

As such, in some implementations, the width between the fingers of the interdigitated metal layer 31 of the DSC 200 can be, for example, 5 μm. Smaller spacing may cause short circuiting, as the porous layer 2, having a thickness of about 10 μm and acting as the photo-anode, may grow laterally during deposition and make contact with the cathode. The width of the photo-anode fingers can range from about 10 μm to 100 μm, such as, for example, 20 μm for acetonirtile-based electrolytic cells.

In some implementations, photolithography can be used to pattern both the DSC 100 having the vertical electrode structure and the DSC 200 having the horizontal electrode structure. The photoresist layer can be applied by various methods, such as, for example, exposure, development and etching.

In other implementations, other techniques can be used to define the interdigitated pattern on the conductive substrate. For example, mechanical methods, such as mechanical scratching can be used to separate neighboring fingers from one another. Mechanical scratching can be performed by, for example, a sharp diamond tip that travels on the surface of a substrate and excavates the substrate. In other examples, a focused laser beam that creates a high, local temperature on the surface of the substrate can be used to create channels as the beam moves along the surface.

In yet other examples, a shallow scratch on a conductive substrate can be created at the separation lines, followed by chemical and/or electrochemical etching of the metal. The etching can be continued until electrical contact between two adjacent fingers completely disappears since etching takes place more readily on the scratched areas. This mechano-chemical method is more controllable relative to the mechanical methods disclosed above, as the electrical contact between two adjacent fingers can be monitored during the etching process.

In examples where the porous layer 2 includes zinc oxide (ZnO), the zinc oxide layers can be formed on a conductive substrate in aqueous solutions. The morphology of the layers can be controlled by adding certain adsorbing ions in the electrolyte to realize structures of wires, rods, plates, or other morphologies. It is possible to grow crystalline ZnO porous layers by electrochemical deposition, which does not require any further heat treatment for crystallization.

In examples where the porous layer 2 includes titanium dioxide (TiO₂), electrochemical growth is typically performed on organic electrolytes. However, titanium dioxide usually requires post treatment at temperatures ranging from about 400° C. to 550° C. to enhance crystallinity. Post treatment is essential to reduce the trap states in the material.

It is to be understood the implementations are not limited to the particular processes, devices, and/or apparatus described which may, of course, vary. It is also to be understood that the terminology used herein is for the purpose of describing particular embodiments only, and is not intended to be limiting. As used in this application, the singular forms “a”, “an” and “the” include plural referents unless the content clearly indicates otherwise.

Reference in the specification to “one embodiment” or “an embodiment” means that a particular feature, structure, characteristic, or function described in connection with the embodiment is included in at least one embodiment herein. The appearances of the phrase “in some embodiments” in the specification do not necessarily all refer to the same embodiment.

Accordingly, other embodiments and/or implementations are within the scope of this application.

What is claimed is:

1. A single-sided dye-sensitized solar cell having a vertical patterned structure, comprising:
a conductive substrate;
a patterned nonconductive insulating layer directly over first portions of the conductive substrate;
an electrocatalyst material layer directly over second portions of the conductive substrate, wherein the second portions of the conductive substrate do not overlap with the first portions of the conductive substrate;
a second conductive layer directly over the patterned nonconductive insulating layer;
a porous layer directly over the second conductive layer;
an electrolyte over the porous layer and the electrocatalyst material layer; and
a transparent sheet over the electrolyte.

2. The single-sided dye-sensitized solar cell of claim 1, further comprising two or more spacers located between the conductive substrate and the transparent sheet at opposite ends of the single-sided dye-sensitized solar cell.

3. The single-sided dye-sensitized solar cell of claim 2, wherein the volume between the two or more spacers, the conductive substrate, and the transparent sheet includes the electrolyte.

4. The single-sided dye-sensitized solar cell of claim 1, wherein the first portions of the conductive substrate and the second portions of the conductive substrate are interdigitated.

5. The single-sided dye-sensitized solar cell of claim 1, wherein the conductive substrate includes one or more conductive materials selected from the group consisting of copper, nickel, chromium, titanium, stainless steel, and silicon.

6. The single-sided dye-sensitized solar cell of claim 1, wherein the patterned nonconductive insulating layer includes one or more nonconductive insulating materials selected from the group consisting of silicon oxides, silicon nitride, zirconium oxide, and aluminum oxide.

7. The single-sided dye-sensitized solar cell of claim 1, wherein the patterned nonconductive insulating layer includes one or more polymers.

8. The single-sided dye-sensitized solar cell of claim 1, wherein the porous layer includes one or more of titanium dioxide and/or zinc oxide.

9. The single-sided dye-sensitized solar cell of claim 8, wherein the titanium dioxide comprises titanium dioxide nanoparticles and the zinc oxide comprises zinc oxide nanoparticles.

10. The single-sided dye-sensitized solar cell of claim 1, wherein the porous layer includes one or more dye sensitizers and/or quantum dot sensitizers.

11. The single-sided dye-sensitized solar cell of claim 1, wherein the electrocatalyst material layer includes one or more electrocatalyst materials selected from the group consisting of platinum and cobalt sulfide.

12. The single-sided dye-sensitized solar cell of claim 1, wherein the second conductive layer includes one or more conductive materials selected from the group consisting of copper, nickel, chromium, titanium, and stainless steel.

13. The single-sided dye-sensitized solar cell of claim 1, wherein the thickness of the second conductive layer ranges from 100 nm to 100 μm.

14. The single-sided dye-sensitized solar cell of claim 1, wherein the width of the patterned nonconductive insulating layer, the second conductive layer, and the porous layer ranges from 10 μm to 100 μm.

15. The single-sided dye-sensitized solar cell of claim 1, wherein the width of the electrocatalyst material layer ranges from 5 μm to 100 μm.

16. The single-sided dye-sensitized solar cell of claim 1, wherein the width of the patterned nonconductive insulating layer, the second conductive layer, and the porous layer is greater than the width of the electrocatalyst material layer.

17. A single-sided dye-sensitized solar cell having a vertical patterned structure, comprising:
a conductive substrate;
a photo-anode comprising:
a patterned nonconductive insulating layer directly over first portions of the conductive substrate,
a second conductive layer directly over the patterned nonconductive insulating later, and
a porous layer directly over the second conductive layer;
a cathode comprising an electrocatalyst material layer directly over second portions of the conductive substrate, wherein the second portions of the conductive substrate do not overlap with the first portions of the conductive substrate;
an electrolyte over the photo-anode and the cathode; and
a transparent sheet over the electrolyte.
